(19) United States
(12) Patent Application Publication
(10) Pub. No.: US 2021/0123139 A1
(43) Pub. Date: Apr. 29, 2021

(54) METHOD AND APPARATUS FOR LOW RESISTANCE CONTACT INTERCONNECTION

(71) Applicant: APPLIED MATERIALS, INC., Santa Clara, CA (US)

(72) Inventors: Chunming ZHOU, Fremont, CA (US); Wenting HOU, San Jose, CA (US); Sree Rangasai KESAPRAGADA, Union City, CA (US)

(21) Appl. No.: 16/997,389

(22) Filed: Aug. 19, 2020

Related U.S. Application Data
(60) Provisional application No. 62/927,229, filed on Oct. 29, 2019.

(51) Int. Cl. C23C 28/02; H01L 21/768; H01L 21/02; H01L 21/285; C23C 16/01; C23C 16/06; C23C 14/16

(52) U.S. Cl. CPC C23C 28/023; H01L 21/76879; H01L 21/02074; C23C 14/16; C23C 16/01; C23C 16/06; H01L 21/28562

(57) ABSTRACT

Methods for processing a substrate are provided herein. The method, for example, includes selectively depositing a first layer of metal within at least one feature on a substrate; depositing a second layer of metal atop the first layer of metal and at least on sidewalls defining the at least one feature; depositing a third layer of metal atop the second layer of metal and within the feature to at least completely fill the at least one feature; and removing some of the second layer of metal or some of the second layer of metal and some of the third layer of metal so that remaining portions of the second layer of metal and the third layer of metal are flush with a top surface of the at least one feature.

### CROSS REFERENCE TO RELATED APPLICATIONS

This application claims the benefit of and priority to U.S. Provisional Patent Application Ser. No. 62/927,229, which was filed on Oct. 29, 2019, the entire contents of which is incorporated herein by reference.

### FIELD

Embodiments of the present disclosure generally relate to a methods and apparatus for processing a substrate, and more particularly, to methods and apparatus for processing substrates to form low resistance contacts.

### BACKGROUND

For aggressive contacts in advanced logic and memory devices, there are many fundamental challenges. For example, for optimum logic and memory device performance, contact resistance needs to be kept to a minimum. Moreover, as advanced logic and memory devices are being developed with very small critical dimensions (CDs) and very high aspect ratios (HARs), gapfill challenges are becoming more difficult to overcome.

Accordingly, the inventors have provided methods and apparatus for processing substrates used for advanced logic and memory devices.

### SUMMARY

Methods and apparatus for processing a substrate are provided herein. In some embodiments, for example, a method for processing a substrate includes selectively depositing a first layer of metal within at least one feature on a substrate; depositing a second layer of metal atop the first layer of metal and at least on sidewalls defining the at least one feature; depositing a third layer of metal atop the second layer of metal and within the feature to at least completely fill the at least one feature; and removing some of the second layer of metal or some of the second layer of metal and some of the third layer of metal so that remaining portions of the second layer of metal and the third layer of metal are flush with a top surface of the at least one feature.

In accordance with at least some embodiments, a method for processing a substrate includes selectively depositing a first layer of metal within at least one feature on a substrate; depositing a second layer of metal atop the first layer of metal and at least on sidewalls defining the at least one feature; depositing a third layer of metal atop the second layer of metal to one of partially fill, completely fill or overfill the at least one feature; and removing some of the sidewalls, some of the third layer of metal, and some of the second layer of metal so that remaining portions of the second layer of metal and the third layer of metal are flush with each other and remaining portions of the sidewalls.

In accordance with at least some embodiments, a nontransitory computer readable storage medium having stored thereon instructions that when executed by a processor perform a method that includes selectively depositing a first layer of metal within at least one feature on a substrate; depositing a second layer of metal atop the first layer of metal and at least on sidewalls defining the at least one feature; depositing a third layer of metal atop the second layer of metal to one of partially fill, completely fill or overfill the at least one feature; and removing some of the sidewalls, some of the third layer of metal, and some of the second layer of metal so that remaining portions of the second layer of metal and the third layer of metal are flush with each other and remaining portions of the sidewalls.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a diagram of a system including apparatus in accordance with at least some embodiments of the present disclosure.

FIG. 2 is a flowchart of a method for processing a substrate in accordance with at least some embodiments of the present disclosure.

FIGS. 3A-3F are diagrams illustrating a substrate being processed using the method of FIG. 2.

FIGS. 4A-4E are diagrams illustrating a substrate being processed using a method similar to that of FIG. 2.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for processing a substrate are provided herein. A method, for example, can be used for processing substrates that require, or otherwise may benefit from, lower contact resistances, smaller critical dimensions, and/or higher aspect ratios, such as when the substrates are used in advanced logic and/or memory devices. For example, one or more metals, e.g., tungsten (W), can be deposited to partially fill one or more features, e.g., vias, trenches, and/or or dual damascene via-chains, formed using one or more dielectrics, on the substrate. Subsequently, another layer of metal, e.g., W, can be deposited atop the first layer of W to form a liner on which another layer of W can be deposited to partially fill, completely fill or overfill the one or more features, thus obtaining lower contact resistances, smaller critical dimensions, and higher aspect ratios for advanced logic and/or memory devices.

For example, in at least some embodiments, a method for processing substrates can include using selective chemical vapor deposition (CVD)/atomic layer deposition (ALD) to partially fill (e.g., a bottom-up gap fill process) one or more features on a substrate with a first layer of W, thus effectively reducing an overall aspect ratio of a feature. Next, physical vapor deposition (PVD) can be used to form a liner and/or a barrier of W atop the first layer of W, which can function as a protection layer for a feature against certain precursor chemistries used for subsequent processes. For example, after the liner W is formed using PVD, a CVD W process that uses precursor chemistries, such as fluorine (which can sometimes react with (or attack) the dielectric forming the feature), can be used to fill the feature.

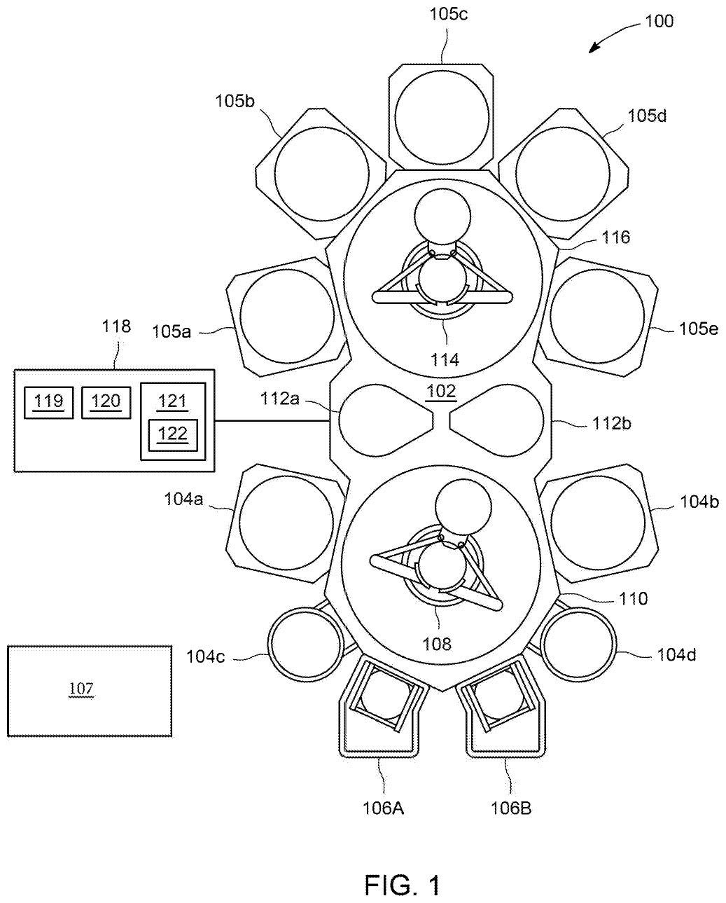

FIG. 1 is a diagram of a system including a multi-chamber processing apparatus (apparatus 100), sometimes referred to as a cluster tool, and a stand-alone chemical-mechanical polishing (CMP) processing chamber 107, and configured to process a substrate in accordance with at least some embodiments of the present disclosure. For example, the apparatus 100 includes a plurality of process chambers mounted to a vacuum transfer chamber. The process chambers can be any type of process chambers including, but not limited to, a PVD chamber, a CVD process chamber, an ALD process chamber, an etch chamber or other type of process chamber.

An example of a PVD process chamber that can be configured for use with the apparatus 100 can be the ENDURA® VERSA® line of stand-alone PVD apparatus, available from Applied Materials, Inc. Santa Clara, Calif. An example of a CVD process chamber that can be configured for use with the apparatus 100 can be the ENDURA® VOLTA® line of stand-alone CVD apparatus, available from Applied Materials, Inc. Similarly, an example of an ALD process chamber that can be configured for use with the apparatus 100 can be the OLYMPIA® line of ALD apparatus, available from Applied Materials, Inc. An example of a CMP process chamber that can be configured for use as the CMP process chamber 107 can be one of the REFLEXION® LK PRIME® line of stand-alone apparatus, available from Applied Materials, Inc.

One or more of the aforementioned apparatus can be combined on an integrated or cluster tool, e.g., ENDURA® line of apparatus available from Applied Materials, Inc., of Santa Clara, Calif. In some embodiments the inventive methods described below may advantageously be performed in a cluster tool such that there are limited or no vacuum breaks while processing. The cluster tool can be configured to perform ALD, CVD, PVD, preclean, epitaxy, etch, photomask fabrication, degas, plasma doping, plasma nitridation and RTP, as well as integrated multi-step processes such as high-k transistor gate stack fabrication. However, the methods described herein may be practiced using other cluster tools having suitable process chambers coupled thereto, or in other process chambers.

For illustrative purposes, the apparatus 100 is shown including a plurality of process chambers embodied in a cluster tool 102 including a first set of process chambers and a second set of process chambers, which can include any combination of process chambers configured to perform a variety of substrate processing operations including a method 200 described below. For example, in at least some embodiments, the first set of process chambers can include a CVD process chamber 104a that is configured to perform CVD on a substrate, an ALD process chamber 104b that is configured to perform ALD on a substrate, a preclean process chamber 104c that is configured to perform a preclean process on a substrate, and/or an etch chamber 104d that is configured to etch a substrate (hereinafter collectively referred to as the process chambers 104). In at least some embodiments, the second set of process chambers can include, for example, a PVD process chamber 105a that is configured to perform PVD on a substrate, a CVD process chamber 105b that is configured to perform CVD on a substrate, an etch process chamber 105c that is configured to etch a substrate, a preclean process chamber 105d that is configured to perform a preclean process on a substrate, and an ALD process chamber 105e that is configured to perform ALD on a substrate (hereinafter collectively referred to as the process chambers 105).

Any of the process chambers 104, 105 may be removed from the cluster tool 102 if not necessary for a particular process to be performed by the cluster tool 102.

The cluster tool 102 can include two load lock chambers 106A, 106B for transferring substrates into and out of the cluster tool 102. Typically, since the cluster tool 102 is under vacuum, the load lock chambers 106A, 106B may “pump down” the substrates introduced into the cluster tool 102. A first robot 108 may transfer the substrates between the load lock chambers 106A, 106B and the process chambers 104, which are coupled to a first central transfer chamber 110, for performing a corresponding process on a substrate.

The first robot 108 can also transfer substrates to/from two intermediate transfer chambers 112a, 112b. The intermediate transfer chambers 112a, 112b can be used to maintain ultrahigh vacuum conditions while allowing substrates to be transferred within the cluster tool 102. A second robot 114 can transfer the substrates between the intermediate transfer chambers 112a, 112b and the process chambers 105, which are coupled to a second central transfer chamber 116.

Additionally, a controller 118 (or processor) is provided and coupled to various components of the cluster tool 102 to control the operation of the process chambers 104, 105 for processing a substrate. The controller 118 includes a central processing unit (CPU) 119, support circuits 120 and a memory or non-transitory computer readable storage medium 121. The controller 118 is operably coupled to and controls one or more energy sources (not shown) configured for use with the process chambers 104, 105 directly, or via computers (or controllers) associated with a particular process chamber and/or support system components.

The controller 118 may be any form of general-purpose computer processor that can be used in an industrial setting for controlling various chambers and sub-processors. The memory, or non-transitory computer readable storage medium, 121 of the controller 118 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 120 are coupled to the CPU 119 for supporting the CPU 119 in a conventional manner. The support circuits 120 include cache, power supplies, clock circuits, input/output circuitry and subsystems, and the like. Inventive methods as described herein, such as the method for processing a substrate (e.g., for low resistance contact interconnection), may be stored in the memory 121 as software routine 122 that may be executed or invoked to control the operation of the one or more energy sources in the manner described herein. The software routine may also be stored and/or executed by a second CPU (not shown) that is remotely located from the hardware being controlled by the CPU 119.

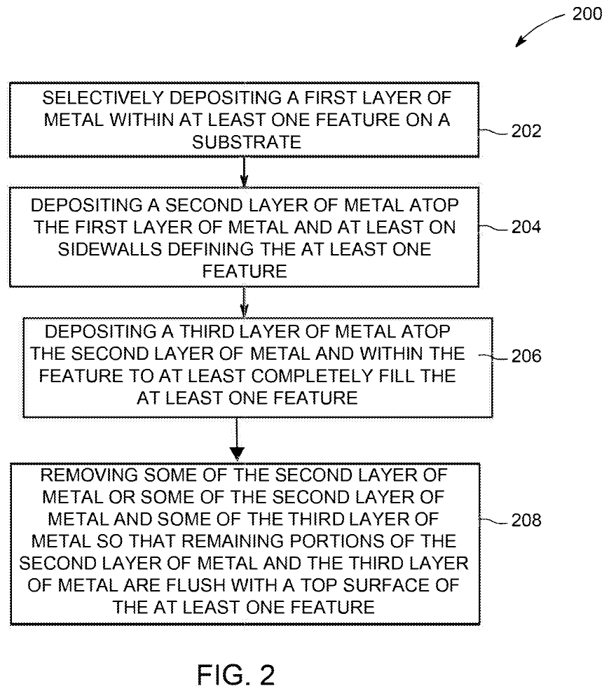

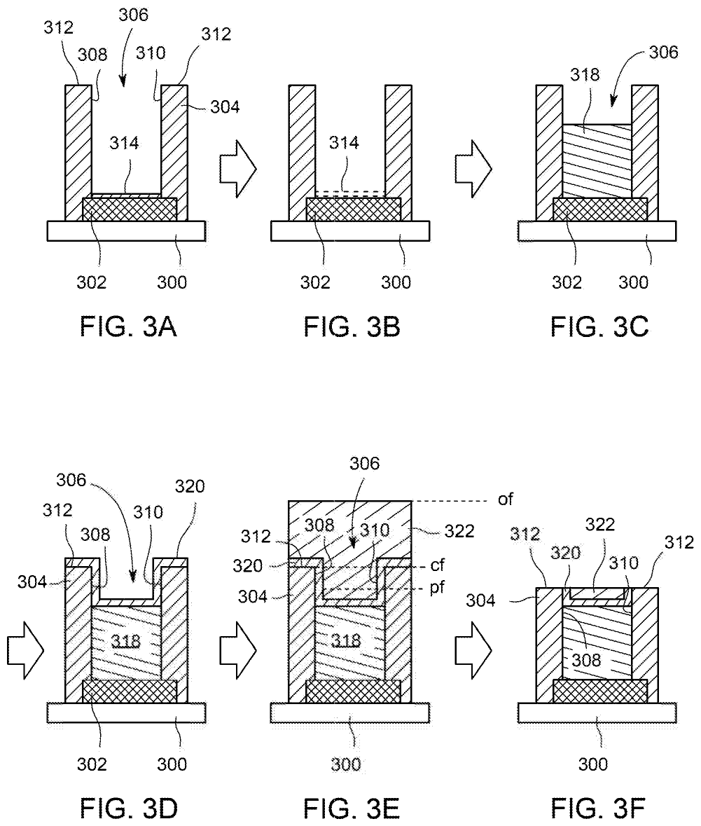

FIG. 2 is a flowchart of a method 200 for processing a substrate, and FIGS. 3A-3F are diagrams illustrating a substrate being processed using the method of FIG. 2, in accordance with at least some embodiments of the present disclosure.

For illustrative purposes, the method 200 is described for processing a prefabricated substrate 300. In at least some embodiments, the substrate 300 can be prefabricated using, for example, one or more of the above-described process chambers, e.g., deposition process chamber, etch process chamber, CMP process chamber, etc., which can be configured for multiple patterning processes and/or one or more fill cycles. Alternatively, in at least some embodiments, the substrate 300300 can be formed using, for example, the cluster tool 102.

The substrate 300 can be formed from any suitable material for forming a substrate, including, but not limited to, silicon, germanium, etc. For example, in at least some embodiments, the substrate 300 can be made from silicon. A base layer 302 can be deposited atop the substrate 300 and can be made from any suitable material for forming a conductive base layer on the substrate 300, including, but not limited to, aluminum (Al), copper (Cu), cobalt (Co), molybdenum (Mo), ruthenium (Ru), titanium (Ti), or tungsten (W). For example, in at least some embodiments, the base layer 302a can be made from tungsten (W) and/or copper (Cu).

Additionally, one or more additional layers can be deposited atop the base layer 302 and/or the substrate 300. For example, in at least some embodiments, an additional layer 304 having one or more features 306 can be deposited atop some of the substrate 300 and/or some of the base layer 302. One feature 306 is shown in the figures. The feature 306 can be a via, trench, and/or or dual damascene via-chain or the like and can have one or more geometrical configurations, including, but not limited to, rectangular, triangular, circular, etc. For example, in at least some embodiments, the feature 306 can have a generally rectangular configuration defined by a top surface 312, a bottom surface (e.g., some of the base layer 302), and four sidewalls (e.g., that define the feature 306). For illustrative purposes, only a first sidewall 308 and a second sidewall 310 of the feature 306 are shown. The layer 304 can be made from one or more suitable dielectric materials for forming the feature 306 including, but not limited to silicon oxide (SiOx), silicon nitride (SiN), or other dielectric materials or films.

Continuing with reference to FIG. 3A, after the substrate 300 is fabricated, the substrate 300 can be transported to one of the load lock chambers 106A, 106B of the cluster tool 102 for further processing using one or more of the process chambers 104, 105 of the cluster tool 102. During transport of the substrate 300 to the cluster tool 102, atmospheric exposure to the substrate 300 can sometimes cause oxide (e.g., metal oxide) to form on a surface (e.g., a top surface) of the base layer 302. For illustrative purposes, a layer of metal oxide 314 is shown atop a portion of the top surface of the base layer 302. Accordingly, in at least some embodiments, prior to depositing an additional layer of material atop the base layer 302, one or more processes can be performed to remove the layer of metal oxide 314.

For example, and with reference to FIG. 3B, the first robot 108 can transfer the substrate 300, under vacuum, from one of the load lock chambers 106A, 106B (e.g. the load lock chamber 106A) to the preclean process chamber 104c (e.g., a fifth process chamber) to perform a preclean (e.g., etch) process to remove a layer of metal oxide 314 (shown in phantom) from a substrate 300 in any suitable manner. Alternatively, prior to transferring the substrate 300 to the cluster tool 102, a separate or remote process chamber (e.g., a preclean or etch process chamber) can be used to remove the layer of metal oxide 314 from the base layer 302.

Next, depending on a incoming substrate (e.g., having a HAR or a low aspect ratio (LAR)), at 202, optionally, a first layer of material can be deposited within a feature on a substrate. For example, and with reference to FIG. 3C, in at least some embodiments, for substrates having a relatively HAR, a first layer of material 318 can be deposited within the feature 306 of the substrate 300 using, for example, the CVD process chamber 104a (e.g., a first process chamber) in any suitable manner. In some embodiments, the ALD process chamber 104b can be used instead of or in conjunction with the CVD process chamber 104a to deposit the first layer of material 318. Alternatively, for substrates having a relatively LAR, such as incoming substrates with vias, trenches, or the like, 202 can be omitted. The first robot 108 can transfer the substrate 300, under vacuum, from the preclean process chamber 104c to the CVD process chamber 104a. The first layer of material 318 can be any suitable metal for forming the first layer of material, including, but not limited to, Al, Co, Cu, Mo, Ru, Ti, and/or W. For example, in at least some embodiments, the first layer of material 318 can be W.

The first layer of material 318 can be deposited to partially fill the feature 306, which can have a height of about 5 nm to about 500 nm, with an AR of about 2 to about 20. For example, in at least some embodiments, such as when the feature 306 includes a height of about 470 nm, a width of about 550 nm, and an aspect ratio of at least about 5.5, such as about 5.5 to about 12, the feature 306 can be filled with the first layer of material 318 to a height of about 30 nm to about 600 nm. In at least some embodiments, the first layer of material 318 can be filled to a height of about one-third (⅓) to about two-thirds (⅔) of the height of the feature 306. The height that the feature 306 is filled with the first layer of material 318 can depend on, for example, a manufacture's preference, the type of material used for the first layer of material 318, contemplated uses of the substrate 300 (e.g., logic and/or memory application), etc.

In at least some embodiments, the CVD process chamber 104a can be configured to perform a selective CVD W process. More particularly, in accordance with the method 200, the CVD process chamber 104a is configured to selectively deposit in any suitable manner (e.g., grow) the W atop the base layer 302, while little or no (e.g., no growth) W is deposited atop or on the dielectric surfaces, e.g., the layer 304 including the first sidewall 308, the second sidewall 310, and/or the top surface 312. That is, at 202 the CVD W fill process atop the base layer 302 within the feature 306 is a bottom up fill process (e.g., low contact resistance), and not a high resistance barrier process and nucleation process as required when using conventional fill processes for filling the feature 306. Examples of suitable selective CVD processes that can be used with the methods and apparatus described herein are disclosed in commonly-owned U.S. patent application Ser. No. 16/803,842, entitled “An INTEGRATION APPROACH OF SURFACE CLEANING AND SELECTIVE TUNGSTEN BOTTOM-UP GROWTH FOR LOW CONTACT RESISTANCE AND SEAM-FREE GAPFILL,” U.S. Patent Publication No. 2018/0145034, entitled “METHODS TO SELECTIVELY DEPOSIT CORROSION-FREE METAL CONTACTS,” U.S. Pat. No. 9,716,012, entitled “METHODS OF SELECTIVE LAYER DEPOSITION,” U.S. Pat. No. 10,256,144, entitled PROCESS INTEGRATION APPROACH OF SELECTIVE TUNGSTEN VIA FILL,” and U.S. Pat. No. 10,395,916, entitled “IN-SITU PRE-CLEAN FOR SELECTIVITY IMPROVEMENT FOR SELECTIVE DEPOSITION.”

Next, at 204, after the first layer of material 318 is deposited atop the base layer 302 to partially fill the feature 306, the first robot 108 can transfer, under vacuum, the substrate 300 from the CVD process chamber 104a to one or more of the aforementioned process chambers so that a second layer of material can be deposited atop the first layer of material 318.

With reference to FIG. 3D, the substrate 300 including the base layer 302 can be transferred from the CVD process chamber 104a to the PVD process chamber 105a (e.g., a second process chamber) to deposit a second layer of material 320 atop a first layer of material 318. For example, in at least some embodiments, the first robot 108 can transfer, under vacuum, the substrate 300 from the CVD process chamber 104a to one of the intermediate transfer chambers 112a, 112b, e.g., the intermediate transfer chamber 112a. Thereafter, the second robot 114 can transfer the substrate 300 from the intermediate transfer chamber 112a to the PVD process chamber 105a.

The second layer of material 320 forms a liner along the first layer of material 318 and/or the top surface 312 of the layer 304 of the substrate 300, which, as noted above, can function as a protection layer for the feature 306 against certain precursor chemistries used for subsequent processes. The second layer of material 320 can be any suitable metal for forming a protection layer including, but not limited to, Al, Co, Cu, Mo, Ru, Ti, and/or W. For example, in at least some embodiments, the second layer of material 320 can be W.

Once transferred, the PVD process chamber 105a can deposit the second layer of material 320 in any suitable manner atop the first layer of material 318 and along a first sidewall 308 and a second sidewall 310 (and/or the third and fourth sidewalls) that define the feature 306 of the substrate 300 (e.g., to form a liner along the first layer of material 318, the first sidewall 308, and the second sidewall 310). Additionally, in at least some embodiments, such as the illustrated embodiment, the second layer of material 320 can be deposited atop the first layer of material 318 and along the first sidewall 308 and the second sidewall 310 (and/or the third and fourth sidewalls) and also on the top surface 312 of the layer 304 of the substrate 300 (e.g., to form a liner along the first layer of material 318, the first sidewall 308, the second sidewall 310, and the top surface 312.

The high ionization plasma used for PVD provides metal ions with superior directionality into the feature 306, thus providing enhanced step coverage into the feature 306. Alternatively, in at least some embodiments, the second layer of material 320 can be deposited using, for example, one or both of the CVD process chamber 104a and/or the ALD process chamber 104b, but such respective processes cannot, typically, achieve as low resistance as PVD, due to higher resistivity film containing impurities that are sometimes present when using CVD/ALD processes to form a liner within a feature.

An amount or thickness of the second layer or material 320 that is deposited on the first layer of material 318, along the first sidewall 308 and the second sidewall 310, and/or the top surface 312 of the substrate 300 can depend on, for example, a manufacture's preference, the type of material used for the second layer of material 320, contemplated uses of the substrate 300 (e.g., logic and/or memory application), etc.

Next, at 206, after the second layer of material 320 is deposited atop the first layer of material 318 and/or on the top surface 312 of the substrate 300, the substrate 300 can be transferred from the PVD process chamber 105a to one or more of the other aforementioned process chambers so that a third layer of material can be deposited atop the second layer of material 320, e.g., to at least partially fill the feature 306 of the substrate 300.

For example, and with reference to FIG. 3E, the substrate 300 including the base layer 302 can be transferred from the PVD process chamber 105a back to the CVD process chamber 104a or another CVD process chamber, such as the CVD process chamber 105b (e.g., a third process chamber) to deposit a third layer of material 322 atop a second layer of material 320 in any suitable manner. In some embodiments, the CVD process chamber 105b can be the same type of process chamber as the CVD process chamber 104a. Alternatively, the CVD process chamber 105b can be a different type of process chamber than the CVD process chamber 104a. For example, the CVD process chamber 105b can be configured to use WF₆ as a precursor material and hydrogen 2 (H₂) as a reduction agent for facilitating deposition of the third layer of 322 atop the second layer of material 320, while the CVD process chamber 104a may not be configured in such a manner. For illustrative purposes, the second robot 114 is described herein as transferring, under vacuum, the substrate 300 from the PVD process chamber 105a to the CVD process chamber 105b.

The amount or thickness of the third layer of material 322 that is deposited atop the second layer of material 320 can depend on, for example, a manufacture's preference, the type of material used for the third layer of material 322, whether a feature 306 of the substrate 300 is to be partially filled, completely filled, or overfilled, contemplated uses of the substrate 300 (e.g., logic and/or memory application), etc.

For example, in at least some embodiments, such as when a liner is formed along the first layer of material 318, the first sidewall 308, and the second sidewall 310, the third layer of material 322 can be deposited atop the second layer of material 320 to completely fill the feature 306. When the feature 306 is completely filled, the second layer of material 320 deposited within the feature 306 (e.g., the area defined by the first sidewall 308 and the second sidewall 310) is completely covered by the third layer or material 322, so that the third layer of material 322 is flush with the top surface 312 of the layer 30e (as indicated by dashed line cf).

In at least some embodiments, the feature 306 can be overfilled, such as when a liner is formed along the first layer of material 318, the first sidewall 308, the second sidewall 310, and the top surface 312. When the feature 306 is overfilled, all of the second layer of material 320 including the portions of the second layer of material 320 that are deposited atop the top surface 312 are covered by the third layer of material 322 (as indicated by dashed line of).

Alternatively, in at least some embodiments, when the feature 306 is partially filled, the third layer of material 322 can be deposited atop the second layer of material 320 to substantially cover the second layer of material 320 deposited within the feature 306 (e.g., a substantial portion of the area defined by the first sidewall 308 and the second sidewall 310e, and as indicated by dashed line pf).

Regardless of how much the feature 306 is filled with the third layer of material 322, the third layer of material 322 should be deposited within the feature 306 so that no gaps or spaces of the third layer of material 322 are present between the first sidewall 308 and the second sidewall 310 of the layer 304.

The third layer of material 322 can be any suitable material, including, but not limited to, Al, Co, Cu, Mo, Ru, Ti, and/or W. For example, in at least some embodiments, the third layer of material 322 can be W.

If at 206, the feature 306 is completely filled with the third layer of material 322 (e.g., the third layer of material 322 is flush (or substantially flush) with the top surface 312 of the layer 304), and none of the second layer of material 320 is present on the top surface 312, the method 200 can end. In some embodiments, however, a CMP process can be performed. For example, even if he third layer of material 322 is flush with the top surface 312 of the layer 304, some of the third layer of material 322 may inadvertently be deposited on the top surface 312.

Accordingly, if at 206, the feature 306 is partially filled, completely filled or overfilled, at 208, at least some of the sidewalls, at least some of a third layer of material, and at least some of a second layer of material can be removed so that remaining portions of the second layer of material 320 and the third layer of material 322 are flush with each other and remaining portions of the sidewalls (e.g., the top surface 312 of the layer 304).

For example, and with reference to FIG. 3F, after a third layer of material 322 is deposited atop the second layer of material 320 of the substrate 300, the substrate 300 can be transferred to one or more of the aforementioned process chambers for further processing. For example, in at least some embodiments, the second robot 114 can transfer, under vacuum, the substrate 300 from the CVD process chamber 105b to one of the intermediate transfer chambers 112a, 112b, e.g., the intermediate transfer chamber 112a. Thereafter, the first robot 108 can transfer the substrate 300 from the intermediate transfer chamber 112 to one of the load lock chambers 106A, 106B (e.g., the load lock chamber 106A).

Next, the substrate 300 can be transferred to a stand-alone CMP process chamber 107 (e.g., a fourth process chamber) to remove some of the third layer of material 322, some of the second layer of material 320, and/or some of a layer 304 (e.g., some of the first sidewall 308, the second sidewall 310 and a top surface 312). That is, the CMP process chamber 107 can be used to polish the substrate 300 to ensure that the second layer of material 320 and the third layer of material 322 are flush with respect to each other and the layer 304 of the substrate 300.

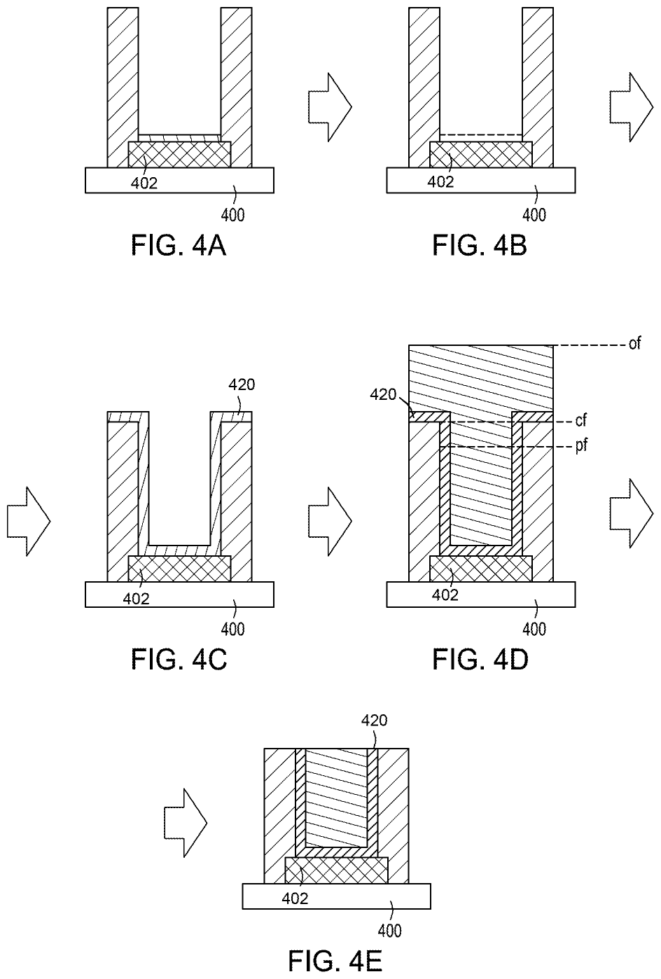

As noted above, in some embodiments, e.g., for substrates having a relatively LAR, such as incoming substrates with vias, trenches, or the like, 202 can be omitted. Accordingly, other than the omission of 202, a substrate 400 can be processed identically as the substrate 300, as shown in FIGS. 4A-4E. For example, rather than depositing a first layer of material atop a base layer 402 at 202, a second layer of material 420 can be deposited directly on the base layer 402, and the method 200 can continue as described above, see FIGS. 4D and 4E, for example.

While the foregoing is directed to embodiments of the present disclosure, other and further embodiments of the disclosure may be devised without departing from the basic scope thereof.

1. A method for processing a substrate, comprising:
selectively depositing a first layer of metal within at least one feature on a substrate;
depositing a second layer of metal atop the first layer of metal and at least on sidewalls defining the at least one feature;
depositing a third layer of metal atop the second layer of metal and within the feature to at least completely fill the at least one feature; and
removing some of the second layer of metal or some of the second layer of metal and some of the third layer of metal so that remaining portions of the second layer of metal and the third layer of metal are flush with a top surface of the at least one feature.

2. The method of claim 1, further comprising removing metal oxide from at least a surface of a base layer of the substrate, the base layer made from at least one of aluminum (Al), copper (Cu), cobalt (Co), molybdenum (Mo), ruthenium (Ru), titanium (Ti), or tungsten (W).

3. The method of claim 2, wherein depositing the first layer of metal comprises using a first process chamber,
wherein depositing the second layer of metal comprises using a second process chamber,
wherein depositing the third layer of metal comprises using at least one of the first process chamber or a third process chamber,
wherein removing at least some of the third layer of metal and at least some of the second layer of metal comprises using a fourth process chamber, and
wherein removing the metal oxide comprises using a fifth process chamber.

4. The method of claim 3, wherein the first process chamber and the third process chamber are configured to perform chemical vapor deposition,
wherein the second process chamber is configured to perform physical vapor deposition,
wherein the fourth process chamber is configured to perform chemical-mechanical polishing, and
wherein the fifth process chamber is configured to perform at least one of a preclean or an etch process.

5. The method of claim 1, wherein depositing the first layer of metal, the second layer of metal, and the third layer of metal comprises depositing at least one of Al, Co, Cu, Mo, Ru, Ti, and/or W.

6. The method of claim 1, wherein the at least one feature is at least one of a via, trench, or dual damascene via-chain.

7. The method of claim 1, wherein the first layer of metal is deposited within the at least one feature to one of a height of about one-third (⅓) to about two-thirds (⅔) of a height of the at least one feature or a height of about 30 nm to about 600 nm.

8. The method of claim 1, wherein depositing the first layer of metal, depositing the second layer of metal, and depositing the third layer of metal are performed using a cluster tool, and wherein removing some of the second layer of metal or some of the second layer of metal and some of the third layer of metal is performed using a stand-alone apparatus.

9. A method for processing a substrate, comprising:
selectively depositing a first layer of metal within at least one feature on a substrate;
depositing a second layer of metal atop the first layer of metal and at least on sidewalls defining the at least one feature;
depositing a third layer of metal atop the second layer of metal to one of partially fill, completely fill or overfill the at least one feature; and
removing some of the sidewalls, some of the third layer of metal, and some of the second layer of metal so that remaining portions of the second layer of metal and the third layer of metal are flush with each other and remaining portions of the sidewalls.

10. The method of claim 9, further comprising removing metal oxide from at least a surface of a base layer of the substrate, the base layer made from at least one of aluminum (Al), copper (Cu), cobalt (Co), molybdenum (Mo), ruthenium (Ru), titanium (Ti), or tungsten (W).

11. The method of claim 10, wherein depositing the first layer of metal comprises using a first process chamber,
wherein depositing the second layer of metal comprises using a second process chamber,
wherein depositing the third layer of metal comprises using at least one of the first process chamber or a third process chamber,
wherein removing at least some of the sidewalls, at least some of the third layer of metal, and at least some of the second layer of metal comprises using a fourth process chamber, and
wherein removing the metal oxide comprises using a fifth process chamber.

12. The method of claim 11, wherein the first process chamber and the third process chamber are configured to perform chemical vapor deposition,
wherein the second process chamber is configured to perform physical vapor deposition,
wherein the fourth process chamber is configured to perform chemical-mechanical polishing, and
wherein the fifth process chamber is configured to perform at least one of a preclean or an etch process.

13. The method of claim 9, wherein depositing the first layer of metal, the second layer of metal, and the third layer of metal comprises depositing at least one of Al, Co, Cu, Mo, Ru, Ti, or W.

14. The method of claim 9, wherein the at least one feature is at least one of a via, trench, or dual damascene via-chain.

15. The method of claim 9, wherein the first layer of metal is deposited within the at least one feature to one of a height of about one-third (⅓) to about two-thirds (⅔) of a height of the at least one feature or a height of about 30 nm to about 600 nm.

16. A nontransitory computer readable storage medium having stored thereon instructions that when executed by a processor perform a method for processing a substrate, comprising:
selectively depositing a first layer of metal within at least one feature on a substrate;
depositing a second layer of metal atop the first layer of metal and at least on sidewalls defining the at least one feature;
depositing a third layer of metal atop the second layer of metal to one of partially fill, completely fill or overfill the at least one feature; and
removing some of the sidewalls, some of the third layer of metal, and some of the second layer of metal so that remaining portions of the second layer of metal and the third layer of metal are flush with each other and remaining portions of the sidewalls.

17. The nontransitory computer readable storage medium of claim 16, further comprising removing metal oxide from at least a surface of a base layer of the substrate, the base layer made from at least one of aluminum (Al), copper (Cu), cobalt (Co), molybdenum (Mo), ruthenium (Ru), titanium (Ti), or tungsten (W).

18. The nontransitory computer readable storage medium of claim 17, wherein depositing the first layer of metal comprises using a first process chamber,
wherein depositing the second layer of metal comprises using a second process chamber,
wherein depositing the third layer of metal comprises using at least one of the first process chamber or a third process chamber,
wherein removing at least some of the sidewalls, at least some of the third layer of metal, and at least some of the second layer of metal comprises using a fourth process chamber, and
wherein removing the metal oxide comprises using a fifth process chamber.

19. The nontransitory computer readable storage medium of claim 18, wherein the first process chamber and the third process chamber are configured to perform chemical vapor deposition,
wherein the second process chamber is configured to perform physical vapor deposition,
wherein the fourth process chamber is configured to perform chemical-mechanical polishing, and
wherein the fifth process chamber is configured to perform at least one of a preclean or an etch process.

20. The nontransitory computer readable storage medium of claim 16, wherein depositing the first layer of metal, the second layer of metal, and the third layer of metal comprises depositing at least one of Al, Co, Cu, Mo, Ru, Ti, and/or W.
